(19) United States
(12) Patent Application Publication
(10) Pub. No.: US 2026/0190763 A1
(43) Pub. Date: Jul. 2, 2026

(54) DISPLAY DEVICE

(71) Applicant: LG Display Co., Ltd., Seoul (KR)

(72) Inventors: Seunghan Paek, Seoul (KR); Sangpyo Hong, Goyang-si (KR); Hyunjin An, Paju-si (KR); Sinchul Kang, Gimpo-si (KR)

(73) Assignee: LG Display Co., Ltd., Seoul (KR)

(21) Appl. No.: 19/222,885

(22) Filed: May 29, 2025

(30) Foreign Application Priority Data
Dec. 31, 2024 (KR) 10-2024-0201886

(51) Int. Cl. H10K 59/80; H10K 102/00

(52) U.S. Cl. CPC H10K 59/871; H10K 2102/311

(57) ABSTRACT

A display device includes: a display panel including a display area in which a pixel array layer is disposed, a fixed area adjacent to the display area, a bendable area adjacent to the fixed area and bent at a predetermined curvature, and a pad area adjacent to the bendable area and disposed under the fixed area; and a driving chip disposed in the pad area of the display panel. The display panel includes a first glass substrate disposed in the display area and the fixed area, and a second glass substrate disposed in the pad area. The first glass substrate includes a first portion disposed in the display area and a second portion disposed in the fixing area. At least one of the second portion of the first glass substrate and the second glass substrate has a smaller thickness than the first portion of the first glass substrate.

### CROSS-REFERENCE TO RELATED APPLICATION

This application claims priority from Korean Patent Application No. 10-2024-0201886, filed on Dec. 31, 2024 in the Korean Intellectual Property Office, and all the benefits accruing therefrom under 35 U.S.C. 119, the entire contents of which are herein incorporated by reference.

### BACKGROUND

### Field

The present disclosure relates to a display device.

### Description of Related Art

Display devices are applied to various electronic devices, such as TV, mobile phones, laptops, and tablets.

The display device includes an organic light-emitting display device (OLED) that emits light by itself, and a liquid crystal display device (LCD) that requires a separate light source.

A bezel area of the display device is recognized by the user and becomes a factor that degrades aesthetics and immersion. Recently, a display device of a narrow bezel design in which a bezel area in which an image of the display device is not displayed is reduced has been in the spotlight.

### SUMMARY

To maximize or improve aesthetics and immersion, research and development are in progress to reduce not only the upper, left, and right bezel areas of the display device but also the lower bezel area of the display device in which a driving chip is mounted. To reduce the lower bezel area of the display device, a technique of bending the lower non-display area of the display panel has been developed.

To bend the lower non-display area of the display panel to which the glass substrate is applied, a bendable area may be employed where a portion of the glass substrate is removed.

There is a problem in that a size of the glass substrate is increased due to the bendable area of the display panel, such that a UPS (unit per sheet) of a mother glass is reduced.

In addition, as the bendable area of the display panel is bent such that a pad area of the display panel is disposed on a rear surface of the display panel, a mounting area of various components of the display device, such as a battery, is reduced.

A purpose of the present disclosure is to provide a display device capable of preventing or suppressing a decrease in an UPS (unit per sheet) of a mother glass substrate by reducing a bendable area of a display panel.

In addition, a purpose of the present disclosure is to provide a display device capable of preventing or suppressing performance degradation of components such as a battery of the display device.

Another purpose of the present disclosure is to provide a display device capable of reducing production energy and reducing greenhouse gas emission.

Purposes according to the present disclosure are not limited to the above-mentioned purposes. Other purposes and advantages according to the present disclosure that are not mentioned may be understood based on following descriptions and may be more clearly understood based on embodiments according to the present disclosure. Further, it will be easily understood that the purposes and advantages according to the present disclosure may be realized using means shown in the claims or combinations thereof.

To achieve these and other advantages and in accordance with the purposes of the disclosure, as embodied and broadly described herein, a display device according to an example embodiment of the present disclosure includes: a display panel including a display area in which a pixel array layer is disposed, a fixed area adjacent to the display area, a bendable area adjacent to the fixed area and bent at a predetermined curvature, and a pad area adjacent to the bendable area and disposed under the fixed area; and a driving chip disposed in the pad area of the display panel, wherein the display panel includes a first glass substrate disposed in the display area and the fixed area, and a second glass substrate disposed in the pad area, wherein the first glass substrate includes a first portion disposed in the display area and a second portion disposed in the fixing area, and wherein at least one of the second portion of the first glass substrate and the second glass substrate has a thickness smaller than a thickness of the first portion of the first glass substrate.

According to example embodiments of the present disclosure, the thickness of the portion of the glass substrate disposed in at least one of the fixed area and the pad area of the display panel overlapping each other in a state in which the bendable area of the display panel has been bent may be reduced, such that the size of the bendable area of the display panel may be reduced and the reduction in the UPS (unit per sheet) of the mother glass for manufacturing the display panel may be prevented or suppressed.

In addition, according to example embodiments of the present disclosure, the tapered area is provided between two portions of the glass substrate having different thicknesses. Thus, it can be easy to attach the support structure to the rear surface of the display panel, and the support structure can be in close contact with the glass substrate of the display panel without any part being lifted.

In addition, according to example embodiments of the present disclosure, the groove is defined in the rear surface of the glass substrate of the display panel and the printed circuit board or the battery is inserted into the groove, such that the size or the thickness of the battery may be increased, and thus the deterioration in the performance of the battery may be prevented or suppressed.

According to example embodiments of the present disclosure, the reduction in the UPS of the mother glass may be prevented or suppressed such that the production energy used for the production of the display device may be reduced, and the emission of greenhouse gas for the production may be reduced.

Effects of the present disclosure are not limited to the effects mentioned above, and other effects not mentioned can be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

The accompanying drawings, which are included to provide a further understanding of the present disclosure and are incorporated in and constitute a part of this application, illustrate example embodiments of the present disclosure and together with the description serve to explain the principles of the disclosure.

FIG. 1 is a plan view illustrating a display device according to an example embodiment of the present disclosure.

FIG. 2 is a rear view illustrating a display device according to an example embodiment of the present disclosure.

FIG. 3 is a cross-sectional view taken along a line III-III in FIGS. 1 and 2;

FIG. 4 is a cross-sectional view illustrating a non-bent state of a display panel according to an example embodiment of the present disclosure.

FIGS. 5 and 6 are cross-sectional views illustrating a non-bent state of a display panel according to example embodiments of the present disclosure.

FIG. 7 is a cross-sectional view illustrating a display device according to an example embodiment of the present disclosure.

FIG. 8 is a cross-sectional view illustrating a display device according to an example embodiment of the present disclosure.

FIG. 9 is a cross-sectional view illustrating a display device according to an example embodiment of the present disclosure.

FIG. 10 is a cross-sectional view illustrating a display device according to an example embodiment of the present disclosure.

### DETAILED DESCRIPTION

Advantages and features of the present disclosure, and a method of achieving the advantages and features will become apparent with reference to example embodiments described below in detail together with the accompanying drawings. However, the present disclosure is not limited to the embodiments as disclosed, but may be implemented in various different forms. Thus, these embodiments are set forth only to make the present disclosure complete, and to clearly inform the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality, unless otherwise specified. Further, descriptions and details of well-known steps and elements may be omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It should be understood that the description herein is not intended to limit the claims to the specific embodiments described. On the contrary, it is intended to cover alternatives, modifications, and equivalents as may be included within the spirit and scope of the present disclosure, including as defined by the appended claims and their equivalents.

A shape, a size, a ratio, an angle, a number, etc., disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, components and/or portions thereof, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list. In interpretation of numerical values, an error or tolerance therein may occur even when there is no explicit description thereof.

In addition, it should also be understood that when a first element or layer is referred to as being present “on” a second element or layer, the first element may be disposed directly on the second element or may be disposed indirectly on the second element with a third element or layer being disposed between the first and second elements or layers. It should be understood that when an element or layer is referred to as being “connected to” or “coupled to” another element or layer, it may be directly connected to or coupled to the other element or layer, or one or more intervening elements or layers may be present therebetween. In addition, it should also be understood that, when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter, and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent”, or “directly before” is indicated.

When a certain embodiment may be implemented differently, a function or an operation specified in a specific block may occur in a different order from an order specified in a flowchart. For example, two blocks in succession may be performed substantially concurrently, or the two blocks may be performed in a reverse order depending on a function or operation involved.

It should be understood that, although the terms “first”, “second”, “third”, and so on may be used herein to describe various elements, components, areas, layers and/or periods, these elements, components, areas, layers and/or periods should not be limited by these terms. These terms are used to refer to one element, component, area, layer or section separately from another element, component, area, layer or period. Thus, a first element, component, area, layer or section as described under could be termed a second element, component, area, layer or period, and vice versa, without departing from the spirit and scope of the present disclosure.

When an embodiment may be implemented differently, functions or operations specified within a specific block may be performed in a different order from an order specified in a flowchart. For example, two consecutive blocks may be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It should be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects”, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Description.

In description of flow of a signal, for example, when a signal is delivered from a node A to a node B, this may include a case where the signal is transferred from the node A to the node B via another node unless a more limiting phrase like ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, example embodiments of the present disclosure will be described with reference to the accompanying drawings. In this regard, a scale of each of components as shown in the drawings may be different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, various example embodiments of the present disclosure will be described in detail with reference to the accompanying drawings.

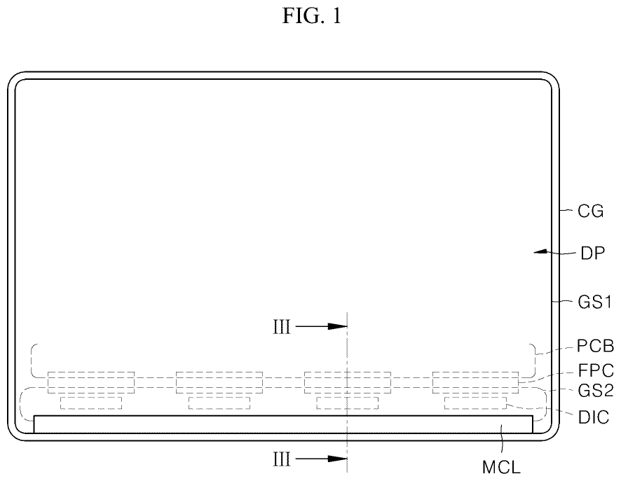

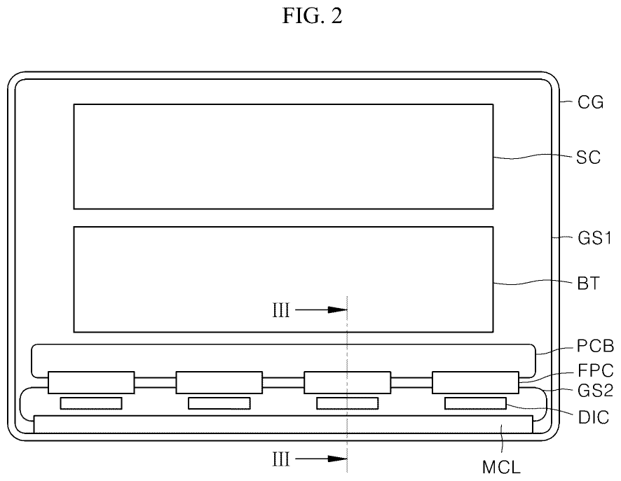

FIG. 1 is a plan view illustrating a display device according to an example embodiment FIG. 2 is a rear view illustrating a display device according to an example embodiment of the present disclosure.

As shown in FIGS. 1 and 2, the display device according to an embodiment of the present disclosure may include a display panel DP, a cover member CG, a driving chip DIC, a printed circuit board PCB, etc.

The cover member CG may be disposed on the display panel DP to protect the display panel DP. The cover member CG may be made of transparent plastic or glass.

The display panel DP may include a first glass substrate GS1 and a second glass substrate GS2. A pixel array layer for displaying an image may be disposed on the first glass substrate GS1 of the display panel DP. The driving chip DIC may be mounted on the second glass substrate GS2 of the display panel DP. The second glass substrate GS2 may be disposed on a rear surface of the first glass substrate GS1. The driving chip DIC on the second glass substrate GS2 may be connected to the pixel array layer on the first glass substrate GS1 via connection lines. The micro coating layer MCL may be disposed at least in an area between the first glass substrate GS1 and the second glass substrate GS2 to protect the connection lines from an external environment and prevent or suppress cracks from being generated in the connection lines.

The printed circuit board PCB may be connected to the second glass substrate GS2 via a flexible circuit film FPC. A timing controller, etc. may be mounted on the printed circuit board PCB. The printed circuit board PCB may also be disposed on the rear surface of the first glass substrate GS1.

A battery BT and at least one system component SC may be disposed on the rear surface of the first glass substrate GS1 of the display panel DP.

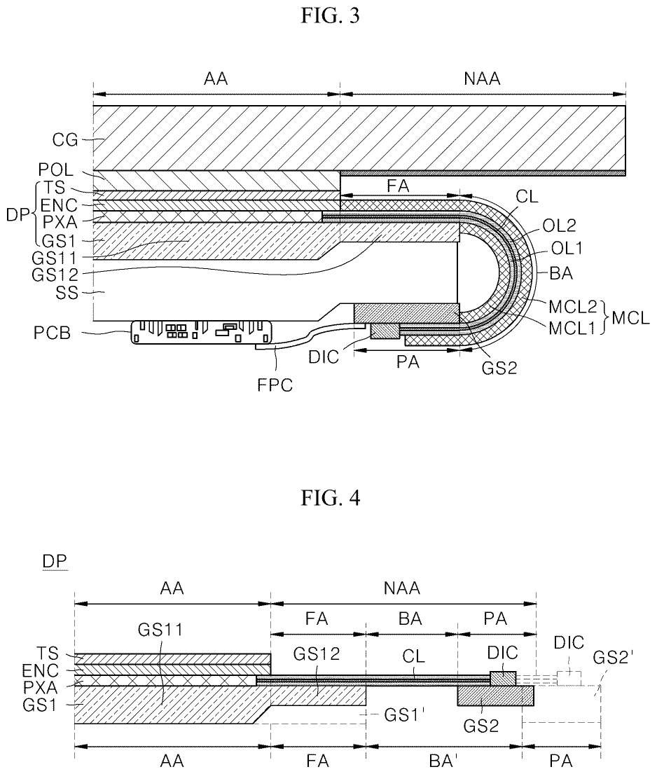

FIG. 3 is a cross-sectional view taken along a line III-III in FIGS. 1 and 2.

As shown in FIG. 3, the display device according to an embodiment of the present disclosure may include the display panel DP, a polarizing plate POL, the cover member CG, a support structure SS, the driving chip DIC, the printed circuit board PCB, etc.

The display panel DP may include a display area AA for displaying an image and a non-display area NAA in which an image is not displayed. The pixel array layer PXA may be disposed in the display area AA of the display panel DP to display an image. The non-display area NAA illustrated in FIG. 3 is a lower non-display area of the display panel DP. The non-display area NAA of the display panel DP may include a fixing area FA, a bendable area BA, and a pad area PA. The bendable area BA may be located between the fixing area FA and the pad area PA.

The driving chip DIC may be mounted in the pad area PA of the display panel DP. Connection lines CL may be disposed in the non-display area NAA of the display panel DP. The connection lines CL may connect the pixel array layer PXA of the display area AA and the driving chip DIC to each other. To reduce the non-display area NAA of the display panel DP as viewed by the user, the pad area PA of the display panel DP may be located under the fixing area FA of the display panel DP. The pad area PA of the display panel DP may vertically overlap the fixing area FA of the display panel DP. To this end, the bendable area BA of the display panel DP may be bent so as to have a predetermined curvature.

The display panel DP may include the first glass substrate GS1 and the second glass substrate GS2 spaced apart from the first glass substrate GS1.

The first glass substrate GS1 may be disposed in the display area AA and the fixing area FA of the display panel DP. A thickness of a portion of the first glass substrate GS1 in the display area AA of the display panel DP may be different from a thickness of a portion of the first glass substrate GS1 in the fixing area FA of the display panel DP. A thickness of a second portion GS12 of the first glass substrate GS1 disposed in the fixing area FA of the display panel DP may be smaller than a thickness of a first portion GS11 of the first glass substrate GS1 disposed in the display area AA of the display panel DP.

The second glass substrate GS2 may be disposed in the pad area PA of the display panel DP. The second glass substrate GS2 may be disposed under the first glass substrate GS1. The second glass substrate GS2 may be disposed under the second portion GS12 of the first glass substrate GS1. A thickness of the second glass substrate GS2 disposed in the pad area PA of the display panel DP may be smaller than the thickness of the first portion GS11 of the first glass substrate GS1 disposed in the display area AA of the display panel DP. The thickness of the second glass substrate GS2 disposed in the pad area PA of the display panel DP may be equal to the thickness of the second portion GS12 of the first glass substrate GS2 disposed in the fixed area FA of the display panel DP.

A glass substrate may not be disposed in the bendable area BA of the display panel DP. A portion of the glass substrate disposed in the bendable area BA of the display panel DP may be removed during the manufacturing process of the display panel DP. Thus, an area between the first glass substrate GS1 and the second glass substrate GS2 may be the bendable area BA.

The display panel DP may include the pixel array layer PXA disposed on the first glass substrate GS1, an encapsulation layer ENC covering the pixel array layer PXA, and a touch sensor layer TS disposed on the encapsulation layer ENC.

The pixel array layer PXA is positioned in the display area AA of the display panel DP and includes a plurality of pixels disposed on the first glass substrate GS1. The pixel array layer PXA may include pixel driving lines that transmit signals to be supplied to the plurality of pixels. In this regard, the pixel driving lines may include data lines, gate lines, and pixel driving power lines. Each pixel may include a pixel circuit, an anode electrode, a light-emitting element layer, and a cathode electrode. The pixel circuit may include a plurality of thin-film transistors and at least one capacitor. The light-emitting element layer may include an organic light-emitting element, a quantum dot light-emitting element, or an inorganic light-emitting element.

The encapsulation layer ENC may protect the pixel array layer PXA or the like from an external impact and may prevent or suppress oxygen and moisture from penetrating into the pixel array layer PXA. The encapsulation layer ENC may include at least one inorganic layer. The encapsulation layer ENC may include at least one inorganic layer and at least one organic layer. For example, the encapsulation layer ENC may include a first inorganic encapsulation layer, an organic encapsulation layer, and a second inorganic encapsulation layer. Each of the first and second inorganic encapsulation layers may include an inorganic material and may include one of a silicon oxide film (SiOx), a silicon nitride film (SiNx), a silicon oxynitride film (SiON), a titanium oxide film (TiOx), and an aluminum oxide film (AlOx). The organic encapsulation layer may be made of one organic material selected from acryl resin, epoxy resin, phenolic resin, polyamide resin, polyimide resin, and benzocyclobutene resin.

The touch sensor layer TS may be disposed on the encapsulation layer ENC. The touch sensor layer TS includes a touch sensor or a touch electrode operating in a mutual capacitance manner or a self-capacitance manner in which a change in capacitance generated according to a user's touch is sensed.

A first organic layer OL1, a connection line CL, and a second organic layer OL2 may be disposed in the non-display area NAA of the display panel DP. The first organic layer OL1, the connection line CL, and the second organic layer OL2 may be disposed in the fixing area FA, the bendable area BA, and the pad area PA of the display panel DP. The connection line CL may be disposed on the first organic layer OL1, and the second organic layer OL2 may be disposed on the connection line CL. Each of the first organic layer OL1 and the second organic layer OL2 may be made of an organic material.

First and second micro coating layers MCL1 and MCL2 may be disposed in the non-display area NAA of the display panel DP. The first and second micro coating layers MCL1 and MCL2 may be made of resin. The first and second micro coating layers MCL1 and MCL2 may protect the connection line CL disposed in the non-display area NAA from an external environment. The first micro coating layer MCL1 may be disposed under the connection line CL, and the second micro coating layer MCL2 may be disposed on the connection line CL. The second micro coating layer MCL2 may be disposed in the fixing area FA, the bendable area BA, and the pad area PA of the display panel DP. The first micro coating layer MCL1 may be disposed only in t he bendable area BA of the display panel DP. To allow a vertical level of a position of the neutral plane to be higher in the bendable area BA of the display panel DP, a thickness of the first micro coating layer MCL 1 may be smaller than a thickness of the second micro coating layer MCL 2. Under presence of the first and second micro coating layers MCL1 and MCL2 in the non-display area NAA of the display panel DP, a vertical level of the position of the neutral plane of the bendable area BA of the display panel DP may be higher, and a reduced tensile stress or compressive stress may be applied to the connection line CL. Accordingly, cracks may be prevented or suppressed from occurring in the connection line CL.

The support structure SS may be disposed under the display panel DP. The support structure SS may be attached to the display area AA and the fixing area FA of the display panel DP to support the display panel DP and to dissipate heat generated from the display panel DP out of the display panel. The pad area PA of the display panel DP may be attached to a portion of the support structure SS disposed under the fixing area FA of the display panel DP. The support structure SS may include a copper layer, a stainless steel layer, and a graphite layer.

The support structure SS may be attached to the first portion GS11 and the second portion GS12 of the first glass substrate GS1 of the display panel DP via an adhesive layer. The second glass substrate GS2 of the display panel DP may be attached to the support structure SS via an adhesive layer. The second glass substrate GS2 of the display panel DP may vertically overlap the second portion GS12 of the first glass substrate GS1 of the display panel DP.

According to an embodiment of the present disclosure, the thickness of the portion of the glass substrate in the fixed area and the pad area overlapping each other while the support structure is interposed therebetween may be reduced in a state in which the bendable area of the display panel is bent. Thus, a size of the bendable area of the display panel may be reduced and the reduction in the USP (unit per sheet) of the mother glass substrate for manufacturing the display panel may be prevented or suppressed.

The first portion GS11 of the first glass substrate GS1 of the display panel DP may have a tapered area at a position thereof in contact with the second portion GS12. A thickness of the tapered area may decrease as the tapered area extends toward the second portion GS12. An upper surface of the support structure SS may be conformal to a shape of a rear surface of the first glass substrate GS1 of the display panel DP. The support structure SS may have an inclined area corresponding to and overlapping the tapered area of the first portion GS11 of the first glass substrate GS1.

According to an embodiment of the present disclosure, the tapered area is positioned between two portions of the glass substrate having different thicknesses, such that it can be easy to attach the support structure to the rear surface of the display panel DP, and the support structure SS can be in close contact with the glass substrate of the display panel DP without any part being lifted.

The flexible circuit film FPC may be connected to an end of the pad area PA of the display panel DP. The printed circuit board PCB may be disposed under the support structure SS and may be supported on the flexible circuit film FPC. A timing controller or the like may be mounted on the printed circuit board PCB. The printed circuit board PCB may be disposed under the display area AA of the display panel DP.

The polarizing plate POL may be disposed on the touch sensor layer TS. The polarizing plate POL may block external light reflected from the thin-film transistors provided in the pixel and the pixel driving lines, thereby improving visibility and contrast ratio of the display device.

The cover member CG may be disposed on the polarizing plate POL. The cover member CG may be attached onto the polarizing plate POL via an adhesive layer.

FIG. 4 is a cross-sectional view illustrating a non-bent state of a display panel according to an embodiment of the present disclosure. FIG. 4 illustrates the display panel of FIG. 3. In addition, FIG. 4 further illustrates a display panel including a first glass substrate GS1′ having a uniform thickness in the display area AA and the fixing area FA of the display panel and a second glass substrate GS2′ having the same thickness as that of the first glass substrate GS1′ as Comparative Example.

As shown in FIG. 4, it may be identified that a length of the bendable area BA of the display panel DP according to an embodiment of the present disclosure is shorter than a length of the bendable area BA′ of the display panel according to the Comparative Example.

This is because, as each of the second portion GS12 of the first glass substrate GS1 disposed in the fixing area FA of the display panel DP and the second glass substrate GS2 disposed in the pad area PA is thicker, the bendable area BA should have a larger radius of curvature and thus the length of the bendable area BA should be larger in order for the pad area PA of the display panel DP being disposed under the fixing area FA.

According to an embodiment of the present disclosure, the thickness of the portion of the glass substrate in each of the fixed area and the pad area of the display which overlap each other while the support structure is interposed therebetween in a state in which the bendable area of the display panel is bent may be reduced, such that the size of the bendable area of the display panel can be reduced, and thus the reduction in the UPS of the mother glass for manufacturing the display panel can be prevented or suppressed.

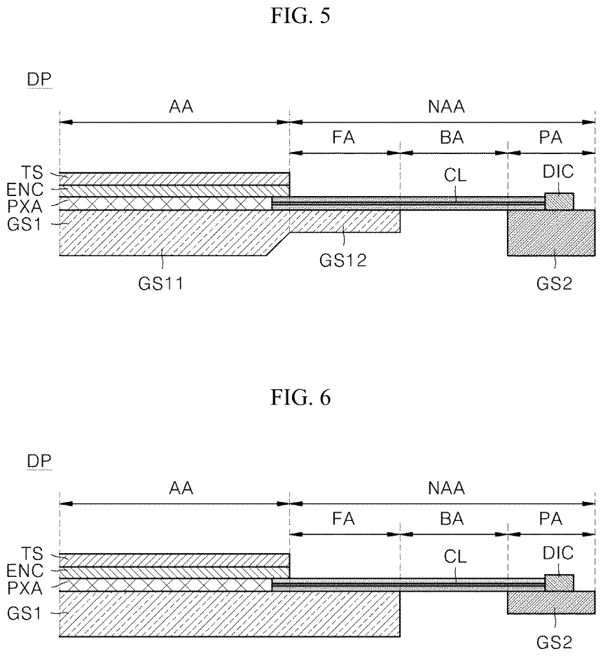

FIGS. 5 and 6 are cross-sectional views illustrating a non-bent state of a display panel according to embodiments of the present disclosure.

As shown in FIG. 5, the display panel DP may include the first glass substrate GS1 and the second glass substrate GS2′ spaced apart from the first glass substrate GS1. The first glass substrate GS1 may be disposed in the display area AA and the fixing area FA of the display panel DP. The second glass substrate GS2′ may be disposed in the pad area PA of the display panel DP.

The thickness of the portion of the first glass substrate GS1 in the display area AA and the thickness of the portion of the first glass substrate GS1 in the fixing area FA of the display panel DP may be different from each other. The thickness of the second portion GS12 of the first glass substrate GS1 disposed in the fixing area FA of the display panel DP may be smaller than the thickness of the first portion GS11 of the first glass substrate GS1 disposed in the display area AA of the display panel DP.

The thickness of the second glass substrate GS2′ may be equal to the thickness of the first portion GS11 of the first glass substrate GS1.

As shown in FIG. 6, the display panel DP may include a first glass substrate GS1′ and the second glass substrate GS2 spaced apart from the first glass substrate GS1′. The first glass substrate GS1′ may be disposed in the display area AA and the fixing area FA of the display panel DP. The second glass substrate GS2 may be disposed in the pad area PA of the display panel DP.

The thickness of the portion of the first glass substrate GS1′ in the display area AA and the thickness of the portion of the first glass substrate GS1′ in the fixing area FA of the display panel DP may be equal to each other.

The thickness of the second glass substrate GS2 may be smaller than the thickness of the first glass substrate GS1.

According to embodiments of the present disclosure, one of the thickness of the portion of the glass substrate in the fixed area of the display panel and the thickness of the glass substrate of the pad area of the display panel may be reduced. In this regard, the fixed area of the display panel and the pad area of the display panel overlap each other while the support structure is interposed therebetween in a state in which the bendable area of the display panel is bent. Thus, a size of the bendable area of the display panel can be reduced, and the reduction in the UPS of the mother glass for manufacturing the display panel can be prevented or suppressed.

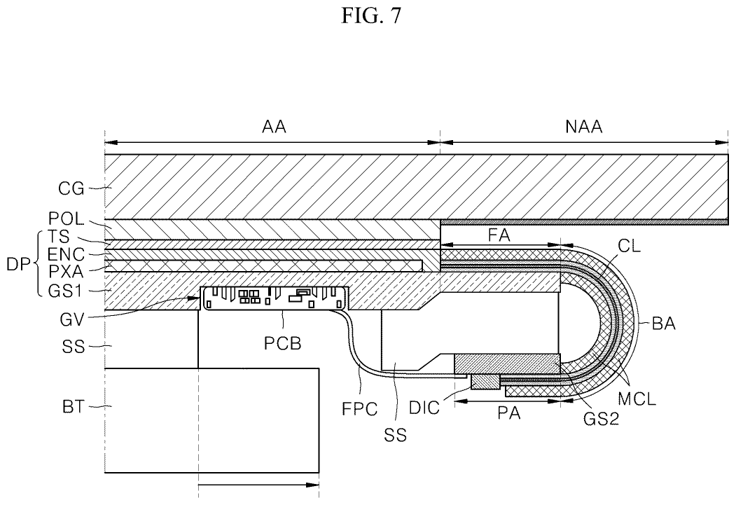

FIG. 7 is a cross-sectional view illustrating a display device according to an embodiment of the present disclosure.

As shown in FIG. 7, a groove GV may be formed in a rear surface of the first portion of the first glass substrate GS1 disposed in the display area AA of the display panel DP.

The printed circuit board PCB may be inserted into the groove GV of the first glass substrate GS1. A depth of the groove GV of the first glass substrate GS1 may be greater than a thickness of the printed circuit board PCB so that the printed circuit board PCB may be entirely inserted therein. Alternatively, the depth of the groove GV of the first glass substrate GS1 may be equal to the thickness of the printed circuit board PCB.

The battery BT may be disposed to overlap at least a portion of the printed circuit board PCB. Accordingly, a length of the battery BT may be further increased by a length of an area where the battery BT and the printed circuit board PCB vertically overlap each other.

The support structure SS may not cover the groove GV of the first glass substrate GS1 so as to be exposed so that the printed circuit board PCB may be disposed in the groove GV of the first glass substrate GS1.

According to an embodiment of the present disclosure, the groove is defined in the rear surface of the glass substrate of the display panel, and the printed circuit board is disposed in the groove, so that the length of the battery can be increased, and thus the deterioration in the performance of the battery can be prevented or suppressed.

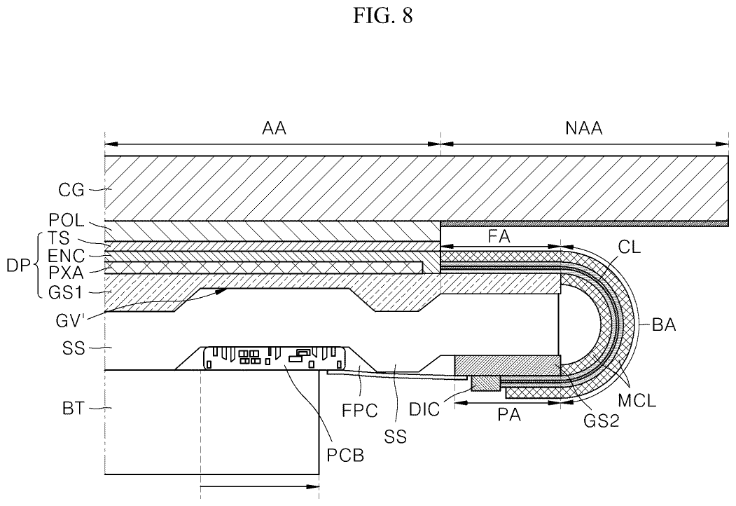

FIG. 8 is a cross-sectional view illustrating a display device according to an embodiment of the present disclosure.

As shown in FIG. 8, a groove GV′ may be formed in a rear surface of the first portion of the first glass substrate GS1 disposed in the display area AA of the display panel DP. A tapered area may be provided at an edge of the groove GV′ formed in the rear surface of the first glass substrate GS1.

The support structure SS can be easily attached to the groove GV′ of the first glass substrate GS1 and thus can be in close contact with the groove GV′ of the first glass substrate GS1 without any part being lifted.

Accordingly, the support structure SS may have a groove overlapping with the groove GV′ of the first glass substrate GS1. The printed circuit board PCB may be inserted into the groove of the support structure SS. The battery BT may be positioned to overlap at least a portion of the printed circuit board PCB. Accordingly, the length of the battery BT can be further increased by a length of the area where the battery BT and the printed circuit board PCB overlap each other.

According to an embodiment of the present disclosure, the groove may be defined in the rear surface of the glass substrate of the display panel and the support structure may have the protrusion corresponding to the groove of the glass substrate and the groove corresponding to the protrusion. In this regard, the printed circuit board may be received in the groove of the support structure. Thus, the length of the battery can be increased, thereby preventing or suppressing the deterioration in the performance of the battery.

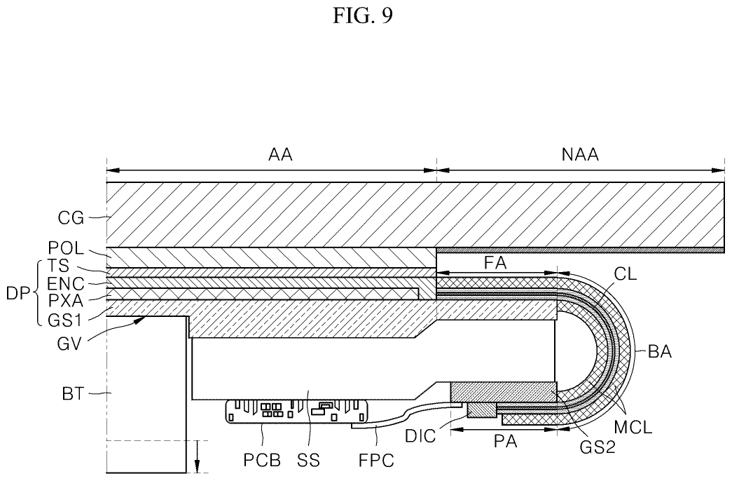

FIG. 9 is a cross-sectional view illustrating a display device according to an embodiment of the present disclosure.

As shown in FIG. 9, a groove GV may be defined in the rear surface of the first portion of the first glass substrate GS1 disposed in the display area AA of the display panel DP. The battery BT may be disposed in the groove GV of the first glass substrate GS1. Accordingly, the thickness of the battery BT can be increased by the depth of the groove GV of the first glass substrate GS1.

The support structure SS may not cover the groove GV of the first glass substrate GS1 so as to be exposed so that the battery BT may be inserted into the groove GV of the first glass substrate GS1.

According to an embodiment of the present disclosure, since the groove is defined in the rear surface of the glass substrate of the display panel and the battery is received in the groove, the thickness of the battery can be increased, and thus the deterioration in the performance of the battery may be prevented or suppressed.

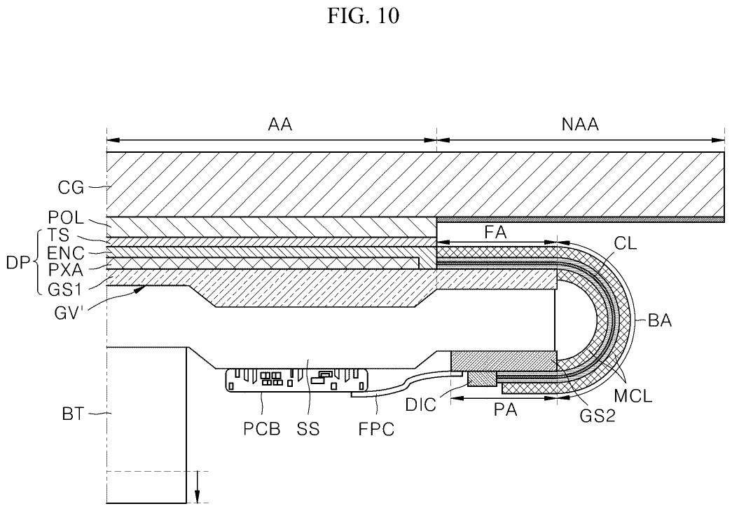

FIG. 10 is a cross-sectional view illustrating a display device according to an embodiment of the present disclosure.

As shown in FIG. 10, a groove GV′ may be formed in the rear surface of the first portion of the first glass substrate GS1 disposed in the display area AA of the display panel DP. A tapered area may be provided at an edge of the groove GV′ formed in the rear surface of the first glass substrate GS1.

Thus, the support structure SS can be easily attached to the groove GV′ of the first glass substrate GS1 and can be in close contact with the groove GV′ of the first glass substrate GS1 without any part being lifted.

Accordingly, the support structure SS may have the groove corresponding to and overlapping with the groove GV′ of the first glass substrate GS1 and defined on a rear surface thereof. The battery BT may be disposed in the groove of the support structure SS. Accordingly, the thickness of the battery BT can be increased by the depth of the groove GV′ of the first glass substrate GS1.

According to an embodiment of the present disclosure, the groove is defined in the rear surface of the portion of the glass substrate of the display panel and the battery is disposed in the groove of the support structure corresponding to and overlapping with the groove of the glass substrate, such that the thickness of the battery can be increased, thereby preventing or suppressing the deterioration in the performance of the battery.

The display device according to various aspects and embodiments of the present disclosure may be described as follows.

One aspect of the present disclosure provides a display device comprising: a display panel including a display area in which a pixel array layer is disposed, a fixed area adjacent to the display area, a bendable area adjacent to the fixed area and bent at a predetermined curvature, and a pad area adjacent to the bendable area and disposed under the fixed area; and a driving chip disposed in the pad area of the display panel, wherein the display panel includes a first glass substrate disposed in the display area and the fixed area, and a second glass substrate disposed in the pad area, wherein the first glass substrate includes a first portion disposed in the display area and a second portion disposed in the fixing area, and wherein at least one of the second portion of the first glass substrate and the second glass substrate has a thickness smaller than a thickness of the first portion of the first glass substrate.

In accordance with some embodiments of the present disclosure, each of the second portion of the first glass substrate and the second glass substrate has the thickness smaller than the thickness of the first portion of the first glass substrate.

In accordance with some embodiments of the present disclosure, the thickness of the second portion of the first glass substrate is equal to the thickness of the second glass substrate.

In accordance with some embodiments of the present disclosure, the second portion of the first glass substrate has the thickness smaller than the thickness of the first portion of the first glass substrate.

In accordance with some embodiments of the present disclosure, the second glass substrate has the thickness smaller than the thickness of the first portion of the first glass substrate.

In accordance with some embodiments of the present disclosure, the first portion of the first glass substrate has a tapered area at a position of the first portion in contact with the second portion.

In accordance with some embodiments of the present disclosure, the display device further comprises a support structure attached to a rear surface of the first glass substrate, wherein the support structure has an inclined area corresponding to the tapered area of the first portion of the first glass substrate.

In accordance with some embodiments of the present disclosure, the display device further comprises: a printed circuit board connected to the pad area of the display panel; and a battery disposed on a rear surface of the display panel, wherein a groove is defined in a rear surface of the first portion of the first glass substrate, wherein the printed circuit board is inserted into the groove, and wherein the battery is positioned to overlap at least a portion of the printed circuit board.

In accordance with some embodiments of the present disclosure, the display device further comprises: a support structure attached to a rear surface of the first glass substrate; a printed circuit board connected to the pad area of the display panel; and a battery disposed on a rear surface of the display panel, wherein a first groove is defined in a rear surface of the first portion of the first glass substrate, wherein the support structure has a second groove defined in a rear surface of the support structure and corresponding to and overlapping the first groove, wherein the printed circuit board is received in the second groove, and wherein the battery is positioned to overlap at least a portion of the printed circuit board.

In accordance with some embodiments of the present disclosure, the display device further comprises a battery disposed on a rear surface of the display panel, wherein a groove is defined in a rear surface of the first portion of the first glass substrate, and wherein the battery is received in the groove.

In accordance with some embodiments of the present disclosure, the display device further comprises: a support structure attached to a rear surface of the first glass substrate; and a battery disposed on a rear surface of the display panel, wherein a first groove is defined in a rear surface of the first portion of the first glass substrate, wherein the support structure has a second groove defined in a rear surface of the support structure and corresponding to and overlapping the first groove, and wherein the battery is inserted into the second groove.

Although some example embodiments of the present disclosure have been described above with reference to the accompanying drawings, the present disclosure is not limited to these example embodiments and may be implemented in various different forms. Those of ordinary skill in the technical field to which the present disclosure belongs will be able to appreciate that the present disclosure may be implemented in other specific forms without departing from the technical idea or features of the present disclosure. Therefore, it should be understood that the embodiments as described above are not restrictive but illustrative in all respects.

What is claimed is:

1. A display device, comprising:
a display panel including a display area in which a pixel array layer is disposed, a fixed area adjacent to the display area, a bendable area adjacent to the fixed area and bent at a predetermined curvature, and a pad area adjacent to the bendable area and disposed under the fixed area; and
a driving chip disposed in the pad area of the display panel,
wherein the display panel includes a first glass substrate disposed in the display area and the fixed area, and a second glass substrate disposed in the pad area,
wherein the first glass substrate includes a first portion disposed in the display area and a second portion disposed in the fixing area, and
wherein at least one of the second portion of the first glass substrate and the second glass substrate has a thickness smaller than a thickness of the first portion of the first glass substrate.

2. The display device of claim 1, wherein each of the second portion of the first glass substrate and the second glass substrate has the thickness smaller than the thickness of the first portion of the first glass substrate.

3. The display device of claim 2, wherein the thickness of the second portion of the first glass substrate is equal to the thickness of the second glass substrate.

4. The display device of claim 1, wherein the second portion of the first glass substrate has the thickness smaller than the thickness of the first portion of the first glass substrate.

5. The display device of claim 1, wherein the second glass substrate has the thickness smaller than the thickness of the first portion of the first glass substrate.

6. The display device of claim 1, wherein the first portion of the first glass substrate has a tapered area at a position of the first portion in contact with the second portion.

7. The display device of claim 6, further comprising a support structure attached to a rear surface of the first glass substrate,
wherein the support structure has an inclined area corresponding to the tapered area of the first portion of the first glass substrate.

8. The display device of claim 1, further comprising:
a printed circuit board connected to the pad area of the display panel; and
a battery disposed on a rear surface of the display panel,
wherein a groove is defined in a rear surface of the first portion of the first glass substrate,
wherein the printed circuit board is inserted into the groove, and
wherein the battery is positioned to overlap at least a portion of the printed circuit board.

9. The display device of claim 1, further comprising:
a support structure attached to a rear surface of the first glass substrate;
a printed circuit board connected to the pad area of the display panel; and
a battery disposed on a rear surface of the display panel,
wherein a first groove is defined in a rear surface of the first portion of the first glass substrate,
wherein the support structure has a second groove defined in a rear surface of the support structure and corresponding to and overlapping the first groove,
wherein the printed circuit board is received in the second groove, and
wherein the battery is positioned to overlap at least a portion of the printed circuit board.

10. The display device of claim 1, further comprising a battery disposed on a rear surface of the display panel,
wherein a groove is defined in a rear surface of the first portion of the first glass substrate, and
wherein the battery is received in the groove.

11. The display device of claim 1, further comprising:
a support structure attached to a rear surface of the first glass substrate; and
a battery disposed on a rear surface of the display panel,
wherein a first groove is defined in a rear surface of the first portion of the first glass substrate,
wherein the support structure has a second groove defined in a rear surface of the support structure, and corresponding to and overlapping the first groove, and
wherein the battery is inserted into the second groove.
